(19) United States
(12) Patent Application Publication
(10) Pub. No.: US 2014/0007922 A1
(43) Pub. Date: Jan. 9, 2014

(54) PHOTOVOLTAIC DEVICE

(71) Applicant: AU OPTRONICS CORPORATION, Hsin-Chu (TW)

(72) Inventors: Chiuan-Ting LI, Hsin-Chu (TW); Kuan-Wen Tung, Hsin-Chu (TW); Huang-Chi Tseng, Hsin-Chu (TW); Chun-Ming Yang, Hsin-Chu (TW); Wei-Jieh Lee, Hsin-Chu (TW)

(73) Assignee: AU Optronics Corporation, Hsin-Chu (TW)

(21) Appl. No.: 13/709,174

(22) Filed: Dec. 10, 2012

(30) Foreign Application Priority Data
Jul. 5, 2012 (CN) 201210231656.5

(51) Int. Cl. H01L 31/052

(52) U.S. Cl. CPC H01L 31/052
USPC 136/251; 136/244

(57) ABSTRACT

A photovoltaic device comprises a photovoltaic panel and a heat sink module. The heat sink module is fastened on a rear surface of the photovoltaic panel. The heat sink module comprises a plurality of fins arranged at intervals, and one surface of each fin defines a wind-facing surface.

### RELATED APPLICATIONS

This application claims priority to Chinese Application Serial Number 201210231656.5, filed Jul. 5, 2012, which is herein incorporated by reference.

### BACKGROUND

1. Technical Field

The present disclosure relates to a photovoltaic device, and more particularly, to a photovoltaic device having a heat sink module.

2. Description of Related Art

A photovoltaic device is typically installed outdoors to receive sunlight and convert the sunlight into electric power. However, when the photovoltaic device is exposed to strong sunlight, the overall temperature of the photovoltaic device is raised to such a high level that the efficiency of the photovoltaic device in converting electric power is reduced, lowering the output electric power of the photovoltaic device. In such circumstances, the heat sink performance required by the photovoltaic device cannot be satisfied by natural air convection and heat conduction. While frame elements covering the periphery of the photovoltaic device may aid in conducting heat, this is not to a sufficient extent that the original converting efficiency of the photovoltaic device is able to be recovered.

### SUMMARY

The present disclosure discloses a photovoltaic device for providing better heat-sink performance, so as to maintain the efficiency of the photovoltaic device in converting electric power, thereby maintaining the original output power thereof.

According to one aspect of the present disclosure, the photovoltaic device comprises a photovoltaic panel and a heat sink module. The photovoltaic panel comprises a front surface and a rear surface opposite to the front surface, wherein the front surface defines a sun-facing surface. The heat sink module comprises at least one sheet member and a plurality of fin rows. The sheet member is provided on the rear surface of the photovoltaic panel. The fin rows are arranged at intervals on the sheet member, and each fin row comprises a plurality of fins spaced from each other. The fins are raised from the sheet member so as to form a plurality of openings on the sheet member in which the shape of each opening is matched to the shape of the fins. Each opening exposes the rear surface of the photovoltaic panel, and one surface of each fin opposite to the corresponding opening defines a wind-facing surface.

The technical solution provided by the present disclosure is novel and more practical compared to conventional configurations. With the provided technical solution, the present disclosure has at least the following advantages:

1. The fins of the heat sink module of the photovoltaic device of the present disclosure can not only increase the heat sink area, but also can function to generate turbulent flow, so as to effectively increase the convectional heat transfer, lower the total temperature of the photovoltaic device, and maintain the effective output power of the photovoltaic device.

2. The heat sink module of the photovoltaic device of the present disclosure is thin, easy to install, simple in structure and light in weight.

3. The fins of the heat sink module of the photovoltaic device of the present disclosure are easy to make, and suitable for mass production, thereby lowering production costs.

### BRIEF DESCRIPTION OF THE DRAWINGS

The present disclosure will be apparent to those skilled in the art by reading the following detailed description of a preferred embodiment thereof, with reference to the attached drawings, in which:

FIG. 1 is an exploded view showing a photovoltaic device according to a first embodiment of the present disclosure;

FIG. 2 is a schematic view showing the photovoltaic device of FIG. 1 in an assembled state;

FIG. 3A is a top view showing a heat sink module of the photovoltaic device of FIG. 1 according to an embodiment of the present disclosure;

FIG. 3B is a partially enlarged view showing a zone M1 of FIG. 3A;

FIG. 4 to FIG. 8 are top views showing the heat sink module of the photovoltaic device of FIG. 1 according to various different embodiments of the present disclosure;

FIG. 9A is a heat distribution diagram simulating a conventional photovoltaic device;

FIG. 9B is a heat distribution diagram simulating the photovoltaic device of FIG. 1;

FIG. 10A is a schematic view showing the photovoltaic device according to a second embodiment of the present disclosure;

FIG. 10B is a schematic view showing the photovoltaic device according to a third embodiment of the present disclosure;

FIG. 11 is a schematic view illustrating the photovoltaic device according to any one of the first, second, or third embodiments of the present disclosure in an installed state;

FIG. 12 is an exploded view showing the photovoltaic device according to embodiments of the present disclosure;

FIG. 13 is a schematic view showing the photovoltaic device in an assembled state according to embodiments of the present disclosure;

FIG. 14 is a cross-sectional view of FIG. 13 taken along 14-14;

FIG. 15A is a top view showing the photovoltaic device according to a fourth embodiment of the present disclosure;

FIG. 15B is a partially enlarged view showing a zone M2 of FIG. 15A;

FIG. 16 is a cross-sectional view of FIG. 15A taken along 16-16;

FIG. 17 is a heat distribution diagram simulating the photovoltaic device of FIG. 15A;

FIG. 18 is an exploded view showing the photovoltaic device according to a fifth embodiment of the present disclosure; and

FIG. 19 is a cross-sectional view showing the photovoltaic device of FIG. 18.

### DESCRIPTION OF THE PREFERRED EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

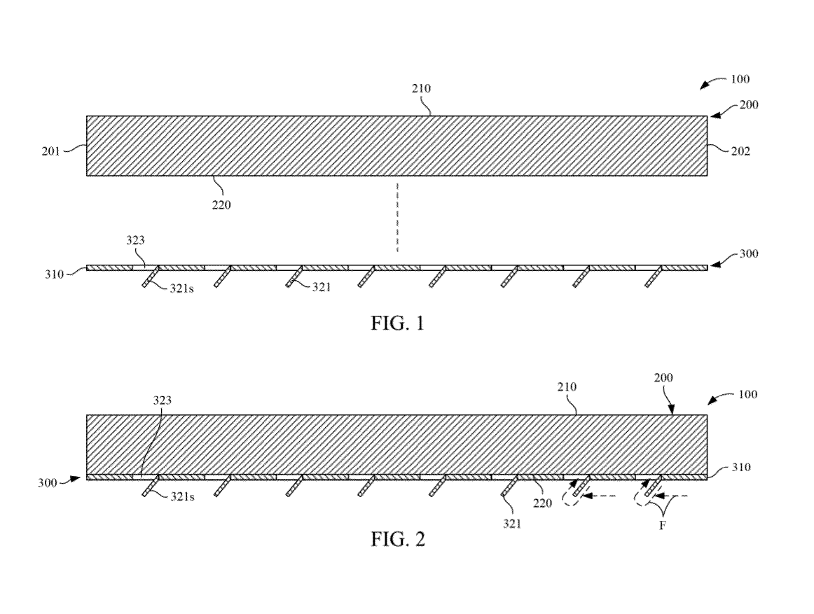

Reference is now made to FIG. 1 and FIG. 2. FIG. 1 is an exploded view showing a photovoltaic device 100 according to a first embodiment of the present disclosure, and FIG. 2 is a schematic view showing the photovoltaic device 100 of FIG. 1 in an assembled state.

According to the present disclosure, the photovoltaic device 100 comprises a photovoltaic panel 200 and a heat sink module 300. The heat sink module 300 is attached to the photovoltaic panel 200 so as to transfer heat with the photovoltaic panel 200.

The photovoltaic panel 200 is also referred to as a solar cell module, and the type thereof is not limited. For example, the solar cell module can be a thin film solar cell module, or a single or poly silicon solar cell module.

The photovoltaic panel 200 has a plurality of sides (e.g., a first side 201 and a second side 202 as shown in FIG. 1), a front surface 210 and a rear surface 220. The first side 201 and the second side 202 are form opposite sides of the photovoltaic panel 200, and the front surface 210 and the rear surface 220 form two main surfaces of the photovoltaic panel 200. The front surface 210 faces the sky for receiving sunlight so as to be defined as a sun-facing surface, and is provided between the first side 201 and the second side 202. The rear surface 220 is a back sheet of the photovoltaic panel 200, and is also provided between the first side 201 and the second side 202. It is noted that the first side 201 and the second side 202 of the photovoltaic panel 200 may be either lengthwise or widthwise sides of the photovoltaic panel 200.

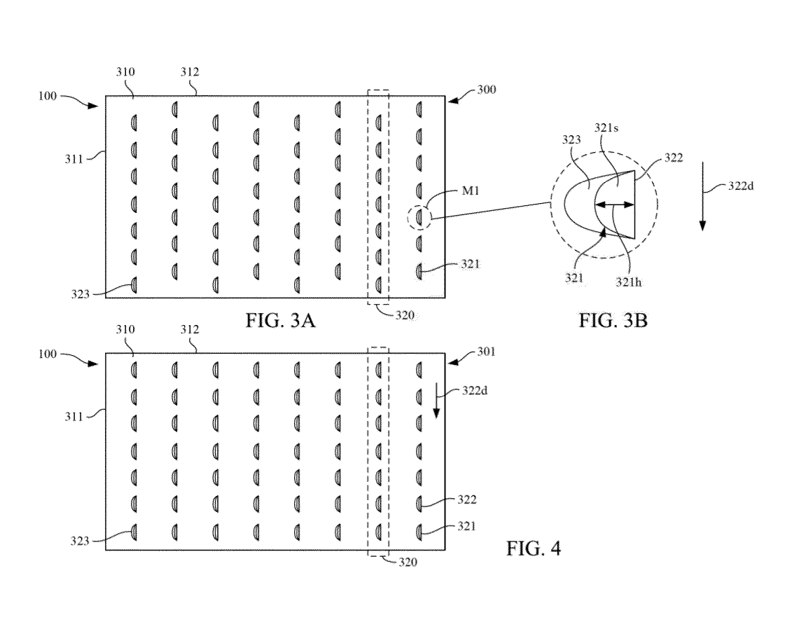

References is now made to FIG. 2, FIG. 3A and FIG. 3B. FIG. 3A is a top view showing the heat sink module 300 of the photovoltaic device 100 of FIG. 1 according to an embodiment of the present disclosure, and FIG. 3B is a partially enlarged view showing a zone M1 of FIG. 3A.

According to this embodiment, the heat sink module 300 comprises a sheet member 310. The sheet member 310 is attached to the rear surface 220 of the photovoltaic panel 200. Since the sheet member 310 is light and thin, when the sheet member 310 is attached to the rear surface 220 of the photovoltaic panel 200, the sheet member 310 will not significantly increase the overall weight of the photovoltaic device 100. Moreover, as the sheet member 310 has minimal weight such that the heat sink module 300 will not be gradually removed from the photovoltaic panel 200 over time, so as to prevent a reduction in the physical contact area between the heat sink module 300 and the photovoltaic panel 200 that would occur with such gradual removal of the heat sink module 300.

The sheet member 310 is formed with a plurality of fin rows 320 on the surface opposite to the photovoltaic panel 200. The fin rows 320 are arranged at intervals on the sheet member 310, and each fin row 320 comprises a plurality of fins 321 spaced from each other. The fins 321 and the sheet member 310 are integrally formed. Moreover, each of the fins 321 is raised from the sheet member 310 to thereby protrude from the surface of the sheet member 310. A crease line 322 is formed between each fin 321 and the sheet member 310, and a plurality of openings 323 are formed at the locations corresponding respectively to the fins 321, in which each opening 323 matches the corresponding fin 321 in shape and size. A specific angle is formed between each fin 321 and the corresponding opening 323.

Each of the openings 323 exposes a portion of the rear surface 220 of the photovoltaic panel 200. The fins 321 function to cause turbulence in a heat sink fluid F, such that the heat sink fluid F enters the openings 323. The heat sink fluid F may be an airflow (e.g., natural wind or forced wind), or may be a liquid (e.g., water, oil, or another fluid used for heat dissipation).

Through such a configuration, when the sun-facing surface 210 of the photovoltaic panel 200 receives sunlight, and the heat sink fluid F flows to a wind-facing surface 321s of each fin 321 (the wind-facing surface 321s of each fin 321 is the surface of the fin 321 opposite to the corresponding opening 323), the heat sink fluid F not only absorbs the heat on the fins 321, but also flows along the wind-facing surface 321s of each fin 321 to thereby generate turbulence, and further flows around each fin 321 to contact the rear surface 220 inside the corresponding opening 323, thereby enabling the heat sink fluid F to dissipate extra heat on the rear surface 220 of the photovoltaic panel 200.

The arrangement of the fins 321 according to one embodiment is disclosed in FIG. 4, which shows a top view of the heat sink module 301 of the photovoltaic device 100 of FIG. 1 according to one embodiment of the present disclosure. According to this embodiment, the fins 321 of the fin rows 320 are arranged in an array, in which all of the fins 321 of the fin rows 320 are linearly arranged in either the transversal or longitudinal direction (in this embodiment, the fins 321 of the fin rows 320 are arranged in the transversal direction). That is, in this embodiment, for each fin row 320, the crease lines 322 of the fins 321 thereof are aligned, and using the extending direction of the crease lines 322 as the extending direction 322d of the fin row 320, the extending direction 322d of the fin row 320 is parallel with the short sides 311 of the sheet member 310. Moreover, in this embodiment, the fins 321 of adjacent fin rows 320 are aligned along the direction of the long sides 312 of the sheet member 310. In some embodiments, the crease lines 322 may extend parallel to the long sides 312 of the sheet member 310 such that each fin row 320 is parallel with the long sides 312 of sheet member 310.

Referring to FIG. 3A, according to another embodiment, the fins 321 of any two adjacent fin rows 320 are arranged in a staggered arrangement. That is, in this embodiment, for each fin row 320, the crease lines 322 of the fins 321 thereof are aligned, and using the extending direction of the crease lines 322 as the extending direction of the fin row 320, the extending direction 322d of the fin row 320 is parallel with the short sides 311 of the sheet member 310. Moreover, in this embodiment, the fins 321 of adjacent fin rows 320 are not aligned along the direction of the long sides 312 of the sheet member 310. However, the fins 312 of every other fin row 320 may be aligned along the direction of the long sides 312 of the sheet member 310. In some embodiments, the crease lines 322 may extend parallel to the long sides 312 of the sheet member 310 such that each fin row 320 is parallel with the long sides 312 of sheet member 310.

With the arrangement of FIG. 3A, the fins 321 of any fin row 320 does not shield the fins 321 on the adjacent fin row 320. As a result, the heat sink fluid is able to be in contact with more fins 321 so as to increase the airflow path (i.e., the heat sink area) and more heat is absorbed from the fins 321.

In practice, with respect to the arrangement of the fins, if the wind blowing direction at the location where of the photovoltaic device 100 is installed is well known, the arranging direction of each of the fins 321 can be specially designed according to the actual environmental condition. In particular, the wind-facing surface 321s of each fin 321 can be designed to face the wind blowing direction, that is, each fin 321 can be designed to be perpendicular to the flowing direction of the heat sink fluid. When each fin 321 is designed to be perpendicular to the flowing direction of the heat sink fluid, the area of the wind-facing surface 321s of each fin 321 that confronts the heat sink fluid is maximized, so as to enhance the heat sink performance of the heat sink module 300.

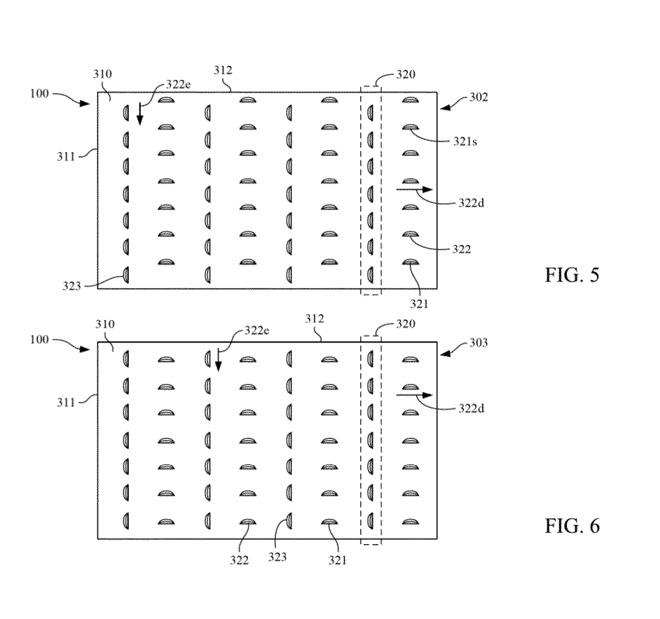

FIG. 5 and FIG. 6 are two top views showing the heat sink module 302, 303 of the photovoltaic device 100 of FIG. 1 according to different embodiments of the present disclosure.

According to the embodiments disclosed in FIG. 5 and FIG. 6, the wind-facing surfaces 321s of the fins 321 of each fin row 320 all face the same direction, e.g., face one of the short sides 311 or one of the long sides 312 of the sheet member 310. If the extending directions 322d, 322e of the crease lines 322 are used for defining the arrangements of the fins 321 of each fin row 320, the crease lines 322 of the fins 321 of each fin row 320 are either parallel with each other and not aligned, or all aligned and parallel with the short sides 311 or the long sides 312 of the sheet member 310 (in this embodiment, they are parallel with the short sides 311 of the sheet member 310).

Moreover, in these embodiments, the fins 321 of any fin row 320 and the fins 321 of the adjacent fin row 320 face different directions, e.g., the extending direction 322d of the crease lines 322 of the fins 321 of any fin row 320 is perpendicular to the extending direction 322e of the crease lines 322 of the fins 321 of the adjacent fin row 320. Accordingly, when the wind blowing direction at the location where the photovoltaic device 100 is installed is frequently in the direction of the short sides 311 or the long sides 312 of the sheet member 310, the fins 321 arranged as described above are able to bring about heat transfer with such two wind blowing directions.

In addition, in the embodiment shown in FIG. 5, the fins 321 of every two adjacent fin rows 320 are arranged in a staggered arrangement, in the manner as described above with reference to FIG. 3A. Moreover, in the embodiment shown in FIG. 6, the fins 321 of every two adjacent fin rows 320 are arranged in an aligned configuration, in the manner as described above with reference to FIG. 4.

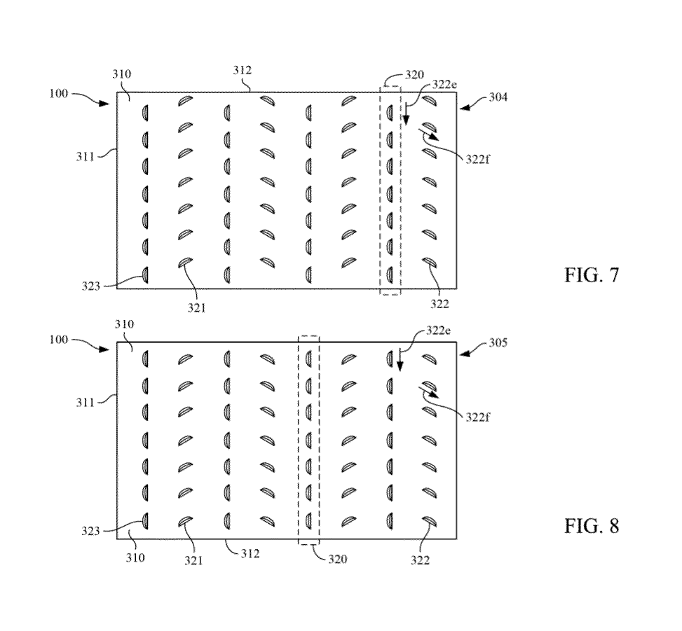

Reference is now made to FIG. 7 and FIG. 8. FIG. 7 and FIG. 8 are two top views showing the heat sink module 304, 305 of the photovoltaic device 100 of FIG. 1 according to different embodiments of the present disclosure.

According to the embodiments disclosed in FIG. 7 and FIG. 8, the wind-facing surfaces 321s of the fins 321 of each fin row 320 all face the same direction, e.g., face one of the short sides 311 or one of the long sides 312 of the sheet member 310. If the extending direction 322e, 322f of the crease lines 322 is used for defining the arrangement of the fins 321 of each fin row 320, the crease lines 322 of the fins 321 of each fin row 320 are parallel with each other.

Moreover, in the embodiments of FIG. 7 and FIG. 8, the fins 321 of any fin row 320 and the fins 321 of another adjacent fin row 320 face different directions. Also, the extending direction 322e of the crease lines 322 of the fins 321 on any fin row 320 is not perpendicular to the extending direction 322f of the crease lines 322 of the fins 321 on another adjacent fin row 320.

Moreover, according to the embodiments disclosed in FIG. 7 and FIG. 8, the fins 321 of every other fin row 320 face one of the long sides 312 of the sheet member 310, but the extending direction 322f of the crease lines 322 of the fins 321 thereof is not parallel with the long sides 312 of the sheet member 310 and instead are at an angle with the long sides 312 of the sheet member 310. Additionally, the fins 321 of the remaining fin rows 320 face one of the short sides 311 of the sheet member 310, and the extending direction 322e of the crease lines 322 of the fins 321 thereof is parallel with the short sides 311 of the sheet member 310.

With the above configuration, when the wind blowing direction at the location where the photovoltaic device 100 is installed is frequently in the direction of the short sides 311 of the sheet member 310 or inclined with respect to the long sides 312 of the sheet member 310, the fins 321 arranged as described above are able to bring about heat transfer with such two wind blowing directions.

In addition, in the embodiment shown in FIG. 7, the fins 321 of any two adjacent fin rows 320 are arranged in a staggered configuration, in the manner as described above with reference to FIG. 3A. Moreover, in the embodiment shown in FIG. 8, the fins 321 of any two adjacent fin rows 320 are arranged in an aligned or array configuration, in the manner as described above with reference to FIG. 4.

It is noted that the scope of the present disclosure is not limited to what has been disclosed above, and other suitable options can be adopted according to actual needs or restrictions.

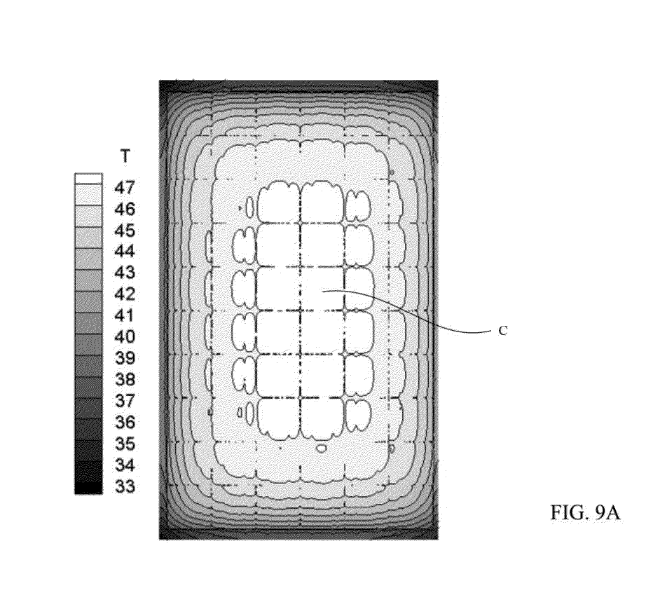

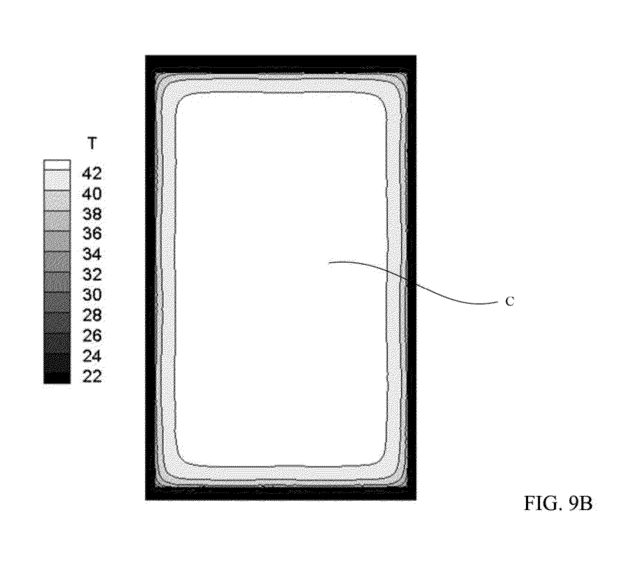

Reference is now made to FIG. 9A and FIG. 9B. FIG. 9A is a heat distribution diagram simulating a conventional photovoltaic device, and FIG. 9B is a heat distribution diagram simulating the photovoltaic device 100 of FIG. 1.

As shown in FIG. 9A, when a conventional photovoltaic device is not provided with a heat sink device, the heat mostly concentrates at a central zone C of the conventional photovoltaic device when exposed to strong sunlight, and there is unbalanced heat distribution at the central zone C, ultimately reducing the efficiency of the photovoltaic device in converting electric power. The highest temperature of the central zone C of the conventional photovoltaic device can exceed 47 degrees Celsius (and may be even up to 48.65 degrees Celsius.

In contrast, as shown in FIG. 9B, when the photovoltaic device 100 provided by the present disclosure is exposed to strong sunlight, with the installation of the heat sink module 300, a central zone C of the photovoltaic device 100 of the present disclosure has balanced heat distribution. This is advantageous with respect to the efficiency of the photovoltaic device in converting electric power. As shown in FIG. 9B, the highest temperature of the central zone C of the photovoltaic device 100 of the present disclosure is about 42 degrees Celsius, e.g., 43.19 degrees Celsius, and this translates into an increased efficiency of the photovoltaic device in converting electric power of 2.5 percent of total efficiency.

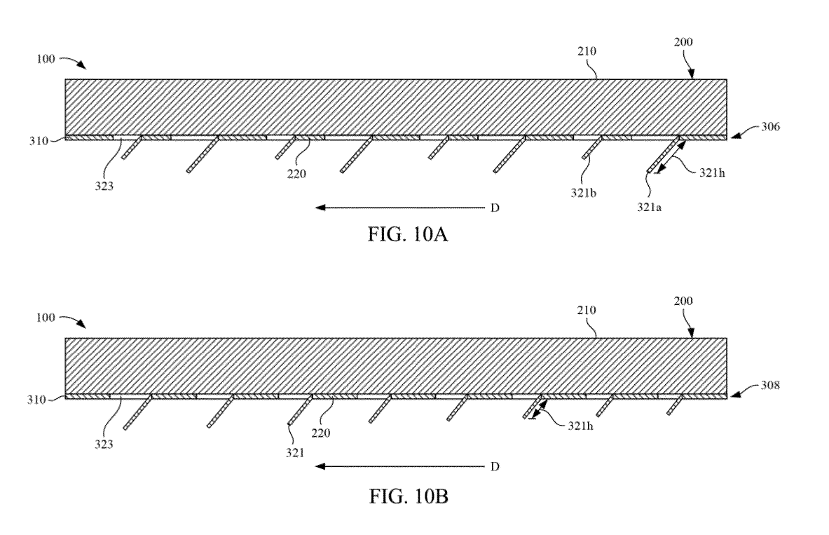

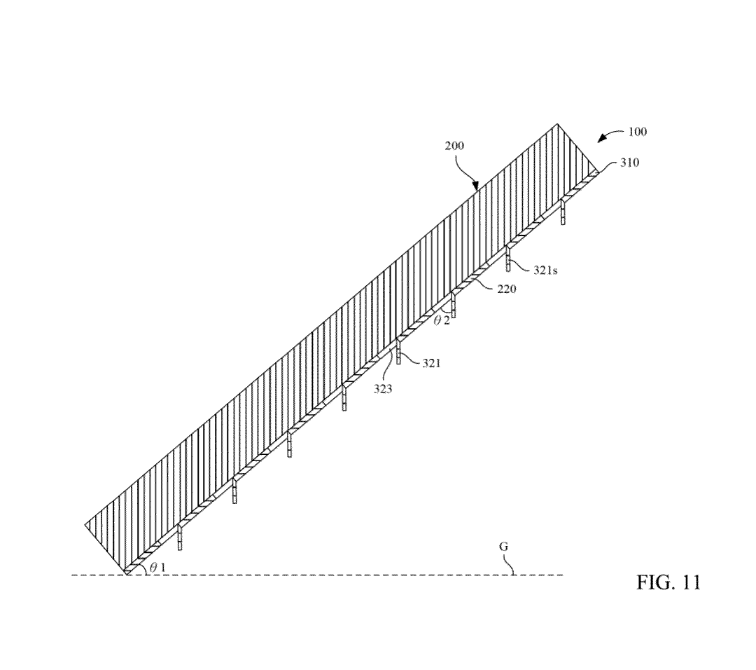

FIG. 10A is a schematic view showing the photovoltaic device 100 according to a second embodiment of the present disclosure.

As shown in FIG. 10A, heights 321h of the fins 321 of the heat sink module 306 that are raised from the sheet member 310 are different, for example, by being raised alternatingly higher and shorter along a direction D which is not limited to the flowing direction of the heat sink fluid. In particular, the fins 321 include longer fins 321a alternated with shorter fins 321b along the direction D It is noted that all of the longer fins 321a can have the same or different lengths, and all of the shorter fins 321b can have the same or different lengths.

FIG. 10B is a schematic view showing the photovoltaic device 100 according to a third embodiment of the present disclosure.

The heights 321h of the fins 321 of the heat sink module 308 raised from the sheet member 310 are not the same. In particular, along the direction D, which is not limited to the flowing direction of the heat sink fluid, the heights 321h of the fins 321 of the fin rows raised from the sheet member 310 are gradually increased. Because the heights 321h of the fins 321 of the fin rows raised from the sheet member 310 are gradually increased along the direction D, the fins 321 having greater heights 321h have greater contact areas with the heat sink fluid compared to the fins 321 having shorter heights 321h so as to increase the heat transfer efficiency of the photovoltaic device 100.

FIG. 11 is a schematic view illustrating the photovoltaic device 100 according to any one of the first, second, or third embodiments of the present disclosure in an installed state.

According to the disclosed embodiment, the photovoltaic device 100 is obliquely installed on an installation surface G, and the installation surface G is parallel with the horizontal plane. Thus, a first included angle θ1 is defined between the photovoltaic device 100 and the installation surface G, a second included angle θ2 is defined between each fin 321 and the corresponding opening 323, and the first included angle θ1 and the second included angle θ2 are complementary angles.

For example, if the first included angle θ1 is 30 degrees, then the second included angle θ2 is 60 degrees, and therefore, the fins 321 are perpendicular to the installation surface G. Through such a configuration, when the flowing direction of the heat sink fluid is parallel with the installation surface G and the heat sink fluid is in contact with the wind-facing surfaces 321s of the fins 321, the greatest area of the wind-facing surface 321s of each fin 321 for confronting the heat sink fluid can be provided. Hence, the fins 321 generate the greatest flow turbulence/flow guide effect.

With respect to the combination of the heat sink module 300 and the photovoltaic panel 200, the sheet member 310 of the heat sink module 300 can be fastened on the rear surface 220 of the photovoltaic panel 200 by methods of latching, adhering or laminating, or by using a heat shrinkable film.

For instance, when the sheet member 310 of the heat sink module 300 is fastened on the rear surface 220 of the photovoltaic panel 200 by latching or laminating, the sheet member 310 of the heat sink module 300 is directly provided on the rear surface 220 of the photovoltaic panel 200. In addition, when the sheet member 310 of the heat sink module 300 is fastened on the rear surface 220 of the photovoltaic panel 200 by adhering, the sheet member 310 of the heat sink module 300 is provided on the rear surface 220 of the photovoltaic panel 200 through an adhesive layer (not shown). Moreover, when using a heat shrinkable film, the sheet member 310 of the heat sink module 300 can be directly provided on the rear surface 220 of the photovoltaic panel 200.

Several examples illustrating the sheet member 310 of the heat sink module 300 being covered on the photovoltaic panel 200 using a heat shrinkable film will now be described. However, the scope of the present disclosure is not limited to the disclosed examples.

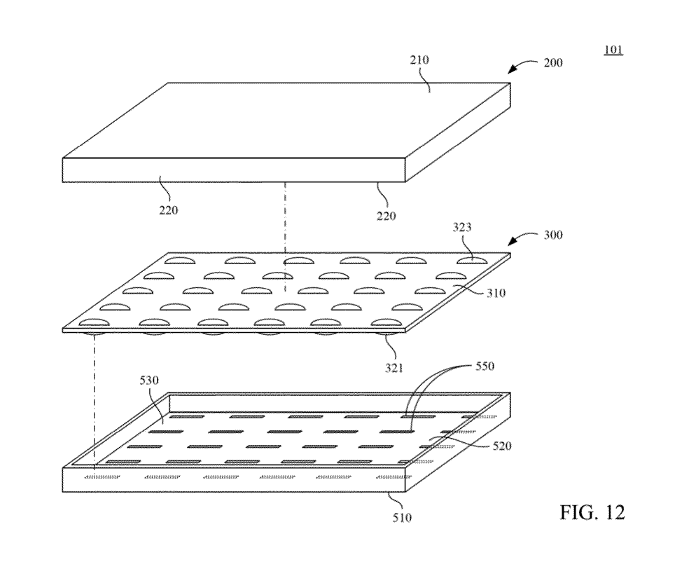

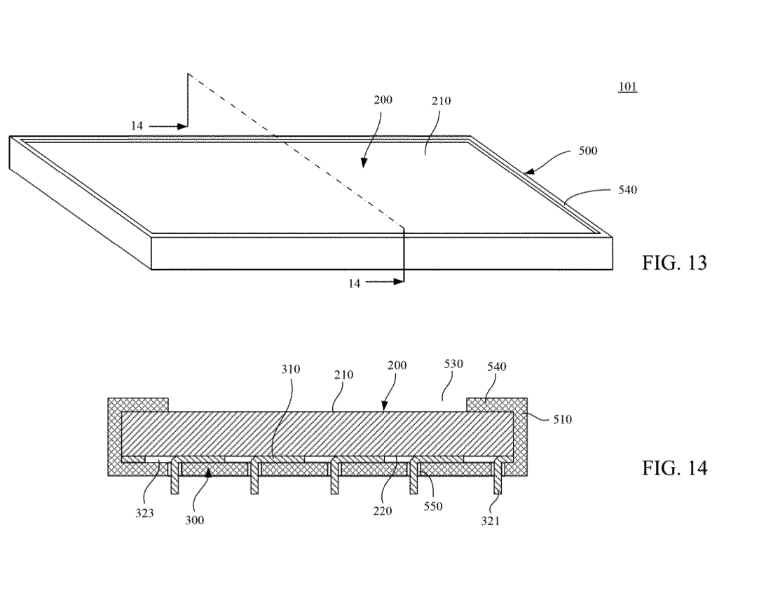

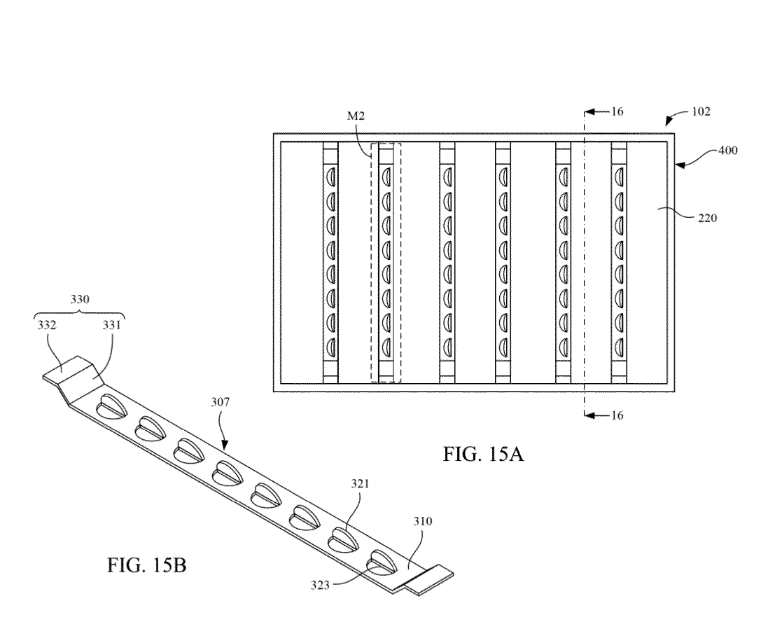

References are now made from FIG. 12 to FIG. 14. FIG. 12 is an exploded view showing the photovoltaic device 101 according to embodiments of the present disclosure; FIG. 13 is a schematic view showing the assembly of the photovoltaic device 101 according to embodiments of the present disclosure; and FIG. 14 is a cross-sectional view of FIG. 13 taken along 14-14.

The heat sink module 300 is further provided with a heat shrinkable unit 500 having a heat shrinking property. When heated by, for example, hot air, the heat shrinkable unit 500 is shrunk, thereby covering or wrapping the sheet member 310 of the heat sink module 300 and a large part of the surface of the photovoltaic panel 200, i.e., the rear surface 220 and all of the lateral sides of the photovoltaic panel 200 are covered by the heat shrinkable unit 500, so as to expose the front surface 210 of the photovoltaic panel 200 only. According to the embodiment disclosed in FIG. 14, edges of the front surface 210 of the photovoltaic panel 200 are also covered or wrapping by the heat shrinkable unit 500, so as to expose the residual part of the front surface 210 of the photovoltaic panel 200 only. At this moment, the sheet member 310 of the heat sink module 300 is disposed between the heat shrinkable unit 500 and the rear surface 220 of the photovoltaic panel 200, and directly provided on the rear surface 220 of the photovoltaic panel 200.

Referring to FIG. 12, the heat shrinkable unit 500 comprises a main body 510, a recessed slot 520, a plurality of flanges 540 (as shown in FIG. 13 and FIG. 14) and a plurality of elongated holes 550. The main body 510 is non-planar, and the shape thereof is not limited and is preferably matched with the photovoltaic panel 200. However, the present disclosure is not limited in this regard.

The recessed slot 520 is formed on one surface of the main body 510, and forms an accommodation space which has a volume that is not less than the volume of the photovoltaic panel 200. The shape of the recessed slot 520 is preferably matched with that of the photovoltaic panel 200. A slot opening 530 of the recessed slot 520 is exposed on the front surface 210 of the photovoltaic panel 200. The elongated holes 550 are formed in a linear shape, and the width thereof is at least greater than or equal to the thickness of the fins 321. The elongated holes 550 are arranged at the bottom of the recessed slot 520, and the arrangement thereof is the same as the arrangement of the fins 321. In this embodiment, the elongated holes 550 are arranged in an array configuration. The elongated holes 550 are respectively aligned with the fins 321, so that the fins 321 to protrude out of the heat shrinkable unit 500.

Manufacturers can design the elongated holes 550 to be correspond to one of the arrangements of the fins 321 disclosed in FIG. 3A to FIG. 8, so as to conform to various configurations of the heat sink modules.

During assembly, (1) the sheet member 310 of the heat sink module 300 is placed in the recessed slot 520, and the fins 321 of the sheet member 310 of the heat sink module 300 are respectively aligned and inserted in the elongated holes 550. Next, (2) with the rear surface 220 of the photovoltaic panel 200 facing downwardly, the photovoltaic panel 200 is received in the recessed slot 520 and disposed above the sheet member 310 of the heat sink module 300. (3) The main body 510 of the heat shrinkable unit 500 is then heated, for example, by applying hot air or taking advantage of the residual high temperature generated through the photovoltaic panel being pressed and laminated, such that the main body 510 of the heat shrinkable unit 500 is shrunk due to the heat. As a result, the sheet member 310 of the heat sink module 300 and the photovoltaic panel 200 are tightly covered in the recessed slot 520. After heating, the flanges 540 of the slot opening 530 of the heat shrinkable unit 500 are protruded towards the slot opening 530 for covering the edges of the front surface 210 of the photovoltaic panel 200, so that the heat shrinkable unit 500 is fastened with the photovoltaic panel 200.

Through such a configuration, the heat shrinkable unit 500 allows the sheet member 310 of the heat sink module 300 to be directly provided on the rear surface 220 of the photovoltaic panel 200, so that no adhesive medium nor slit is formed between the sheet member 310 of the heat sink module 300 and the rear surface 220 of the photovoltaic panel 200, thereby preventing the generation of heat resistance.

In addition, regardless of the weight of the sheet member 310 of the heat sink module 300, because the heat shrinkable unit 500 is tightly fastened on the photovoltaic panel 200, the sheet member 310 of the heat sink module 300 is prevented from being released from the rear surface 220 of the photovoltaic panel 200 after a long period of use. This aids in ensuring that a high level of heat sink performance is maintained.

It is noted that since the photovoltaic panel 200 is provided with structural strength after being covered by the heat shrinkable unit 500, the photovoltaic panel 200 does not require an additional fastening frame, thereby reducing the total weight of the photovoltaic device. However, the present disclosure is not limited to what has been described above, and in some circumstances, the photovoltaic panel can be additionally provided with a fastening frame after being covered by the heat shrinkable unit 500.

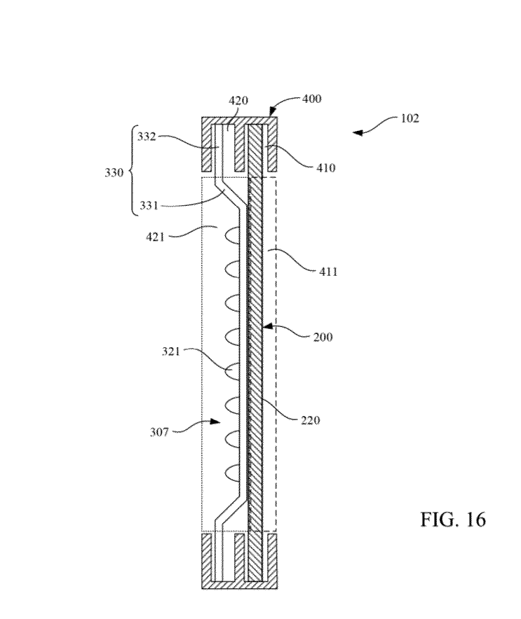

References are now made to FIG. 15A, FIG. 15B and FIG. 16. FIG. 15A is a top view showing the photovoltaic device 102 according to a fourth embodiment of the present disclosure, FIG. 15B is a partially enlarged view showing a zone M2 of FIG. 15A, and FIG. 16 is a cross-sectional view of FIG. 15A taken along 16-16.

According to this embodiment, the photovoltaic device 102 further comprises a fastening frame 400. The fastening frame 400 comprises a first mount slot 410 and a second mount slot 420. The first mount slot 410 defines a first layer of space 411. The second mount slot 420 defines a second layer of space 421. The second layer of space 421 and the first layer of space 411 are adjacent to each other in a stacked configuration. The photovoltaic panel 200 is mounted in the first mount slot 410 and the first layer of space 411. The heat sink module 307 is mounted in the second mount slot 420 and the second layer of space 421.

The heat sink module 307 further comprises two leaning parts 330. The two leaning parts 330 are disposed at two opposite sides of the sheet member 310, and are disposed on a different plane from the sheet member 310. Preferably, the two leaning parts 330 are integrally formed with the sheet member 310. Each leaning part 330 comprises a connecting sheet 331 having elasticity and a leaning sheet 332. The connecting sheet 331 is inclined from one side of the sheet member 310 and towards the direction away from the sheet member 310 and the photovoltaic panel 200, and is connected with the sheet member 310 and the leaning sheet 332. The leaning sheet 332 is parallel with the sheet member 310, and is disposed on a different plane from the sheet member 310.

When the leaning sheets 332 of the two leaning parts 330 are respectively received at two opposite sides of the second mount slot 420, and are respectively pushed against inner walls of the second mount slot 420 of the fastening frame 400 towards the direction opposite to the photovoltaic panel 200, the sheet member 310 is biased by the leaning sheet 332 and the connecting sheet 331 to push against the rear surface 220 of the photovoltaic panel 200 in the direction towards the photovoltaic panel 200. Therefore, the sheet member 310 of the heat sink module 307 can be fastened on the rear surface 220 of the photovoltaic panel 200 through the installation of the two leaning parts 330 as described above.

In addition, due to the weight of the photovoltaic device 102 or due to environmental stress when the photovoltaic device 102 is installed outdoors (e.g., stresses associated with wind or snow), the photovoltaic device 102 may become bent or deformed. However, through use of the leaning parts 330 of the heat sink module 307 biasing the sheet member 310 to push against the rear surface 220 of the photovoltaic panel 200, the heat sink module 307 provides a supporting function to the photovoltaic device 102, so as to prevent deformation and even breaking of the photovoltaic device 102. As a result, the working performance of the photovoltaic device 102 is ensured

Referring to FIG. 15A, the heat sink module 307 comprises a plurality of the sheet members 310 arranged at intervals on the rear surface 220 of the photovoltaic panel 200. Through such a configuration, heat transfer can be uniformly carried out with the photovoltaic panel 200, and the supporting force can also be uniformly applied to the photovoltaic panel 200.

Each sheet member 310 in FIG. 15A also can be formed with a plurality of fin rows 320. Moreover, the fins 321 of the plural fin rows 320 of each sheet member 310 can be arranged with the staggered arrangement or the array arrangement, as fully described above.

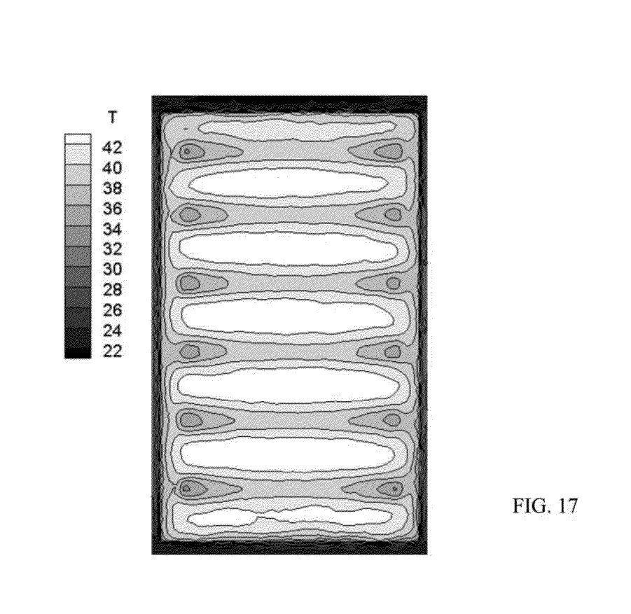

Reference is now made to FIG. 15A and FIG. 17. FIG. 17 is a heat distribution diagram simulating the photovoltaic device 102 of FIG. 15A.

As shown in FIG. 17, in this embodiment of the present disclosure, when the photovoltaic device 102 is subject to strong sunlight, due to the configuration of the plural heat sink modules 307, side-by-side heat distribution occurs on one surface of the photovoltaic device 102 of the present disclosure. As a consequence, the uniformity of heat distribution is increased, and the efficiency of the photovoltaic device 102 in converting electric power is also increased. As shown in FIG. 17, the highest temperature of the photovoltaic device 102 of the present disclosure is only about 42 degrees Celsius, and this translates into an increased efficiency of the photovoltaic device in converting electric power of 2.5 percent of total efficiency.

According to the present disclosure, the material, quantity and size of the aforementioned sheet member is not limited and can be designed according to actual needs and restrictions. In the embodiments of the present disclosure, for example, the material of the sheet member can be metal, the quantity thereof can be one or more, and the size thereof can be substantially the same as the area of the rear surface of the photovoltaic panel.

According to the present disclosure, the manufacturing method of the fins and the openings of the sheet member are not limited and can be designed according to actual needs or restrictions. For example, a punching method or sheet metal method may be used for the fins and openings of the sheet member. In the embodiments of the present disclosure, a punching method is used for the fins and the openings of the sheet member.

According to the present disclosure, the shape of the openings is not limited and can be designed to be semicircular, scale-like, triangular, rectangular or other geometric shapes. In the embodiments of the present disclosure, the shape of the openings is semicircular or scale-like. According to the present disclosure, the openings are not limited to be completed (as shown in FIG. 12) (or not completed).

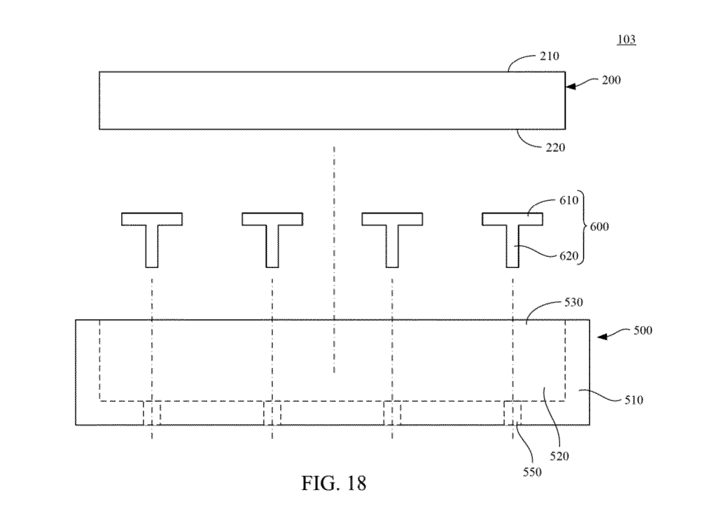

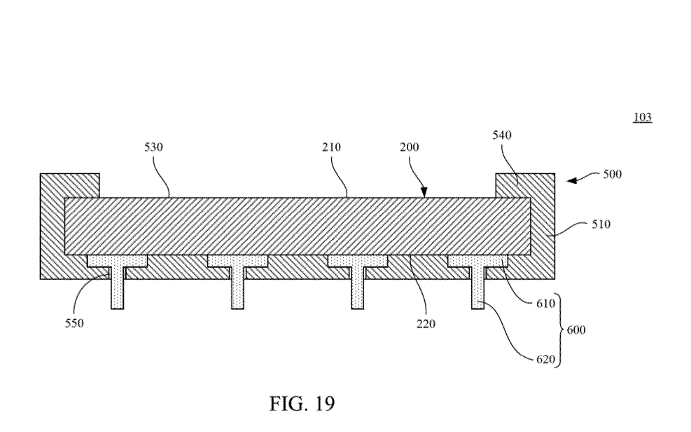

Reference is now made to FIG. 18 and FIG. 19. FIG. 18 is an exploded view showing the photovoltaic device 103 according to a fifth embodiment of the present disclosure, and FIG. 19 is a cross-sectional view showing the photovoltaic device 103 of FIG. 18.

According to the fifth embodiment of the present disclosure, in order to effectively reduce the weight of the heat sink module, the sheet member of the heat sink module omitted and replaced by a plurality of individual fins 600, according to actual needs and restrictions.

For example, in this embodiment, each fin 600 is an individual member, and the transversal cross section thereof is in a T shape. In particular, each fin 600 comprises a transversal piece 610 and a longitudinal piece 620. One end of the longitudinal piece 620 is connected to one side of the transversal piece 610, and the longitudinal piece 620 is perpendicular to the transversal piece 610.

During assembly, (1) the ends of the longitudinal pieces 620 of the fins 600 not connected to the transversal pieces 610 are respectively aligned and inserted in the corresponding elongated holes 550, such that the transversal pieces 610 of the fins 600 are disposed in the recessed slot 520. Next, (2) with the rear surface 220 of the photovoltaic panel 200 facing downwardly, the photovoltaic panel 200 is received in the recessed slot 520 and disposed above the transversal pieces 610 of the fins 600. Subsequently, (3) the main body 510 of the heat shrinkable unit 500 is heated by, for example, applying hot air or taking advantage of the residual high temperature generated through the photovoltaic panel being pressed and laminated, such that the main body 510 of the heat shrinkable unit 500 is shrunk due to the heat. As a result, the transversal pieces 610 of the fins 600 of the heat sink module 300 and the photovoltaic panel 200 are tightly covered in the recessed slot 520. After heating, the main body 510 of the heat shrinkable unit 500 covers both the transversal pieces 610 of the fins 600 and the rear surface 220 of the photovoltaic panel 200. In addition, the flanges 540 of the slot opening 530 of the heat shrinkable unit 500 are protruded towards the slot opening 530 for covering the edges of the front surface 210 of the photovoltaic panel 200, and thus, the heat shrinkable unit 500 can be fastened with the photovoltaic panel 200.

Although the present disclosure has been described with reference to the preferred embodiments thereof, it is apparent to those skilled in the art that a variety of modifications and changes may be made without departing from the scope of the present disclosure which is intended to be defined by the appended claims.

The reader's attention is directed to all papers and documents which are filed concurrently with this specification and which are open to public inspection with this specification, and the contents of all such papers and documents are incorporated herein by reference.

All the features disclosed in this specification (comprising any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A photovoltaic device, comprising:
a photovoltaic panel comprising a front surface and a rear surface opposite to the front surface, wherein the front surface defines a sun-facing surface; and
a heat sink module fastened on the rear surface of the photovoltaic panel, comprising a plurality of fins arranged at intervals, one surface of each of the fins defines a wind-facing surface.

2. The photovoltaic device according to claim 1, wherein the heat sink module further comprises:
at least one sheet member provided on the rear surface of the photovoltaic panel, the fins being arranged on the sheet member thereby forming a plurality of fin rows,
wherein the fins are raised from the sheet member so as to form a plurality of openings on the sheet member, the shape of the openings is matched with the shape of the fins, each of the openings exposes the rear surface of the photovoltaic panel, and each of the wind-facing surfaces is arranged to be opposite to the corresponding opening.

3. The photovoltaic device according to claim 2, wherein the fins of every two adjacent fin rows are arranged in a staggered arrangement.

4. The photovoltaic device according to claim 2, wherein the fins of the fin rows are arranged in an array arrangement.

5. The photovoltaic device according to claim 2, wherein a crease line is formed between each of the fins and the sheet member, and an extending direction of the crease lines of the fins is parallel or not parallel with one lateral side of the sheet member.

6. The photovoltaic device according to claim 2, wherein a crease line is formed between each of the fins and the sheet member, and extending directions of the crease lines of the fins of every two adjacent fin rows are parallel or not parallel with each other.

7. The photovoltaic device according to claim 6, wherein the extending directions of the crease lines of the fins of every two adjacent fin rows are perpendicular to each other.

8. The photovoltaic device according to claim 2, wherein the heights of the fins of the fin rows raised from the sheet member are different.

9. The photovoltaic device according to claim 2, wherein the heights of the fins of the fin rows raised from the sheet member are alternatingly raised higher and shorter.

10. The photovoltaic device according to claim 2, wherein the heights of the fins of the fin rows raised from the sheet member are gradually increased along one direction.

11. The photovoltaic device according to claim 2, wherein each of the fins is arranged to be perpendicular to a flowing direction of a heat sink fluid.

12. The photovoltaic device according to claim 2, wherein the photovoltaic device is inclinedly installed on an installation surface, a first included angle is defined between the photovoltaic device and the installation surface, a second included angle is defined between each fin and the corresponding opening, and the first included angle and the second included angle are complementary angles.

13. The photovoltaic device according to claim 2 further comprising:
a heat shrinkable unit covering the sheet member and the photovoltaic panel after being heated and shrunk, such that only the front surface of the photovoltaic panel is exposed,
wherein the sheet member is disposed between the heat shrinkable unit and the rear surface of the photovoltaic panel, and directly provided on the rear surface of the photovoltaic panel.

14. The photovoltaic device according to claim 13, wherein the heat shrinkable unit comprises:
a main body;
a recessed slot formed in the main body for accommodating the sheet member and the photovoltaic panel;
a slot opening formed on one surface of the main body, the slot opening communicating with the recessed slot and exposing the front surface of the photovoltaic panel; and
a plurality of elongated holes arranged at a bottom of the recessed slot, the fins protruding into the elongated holes, respectively.

15. The photovoltaic device according to claim 2 further comprising:
a fastening frame comprising a first mount slot and a second mount slot, wherein the photovoltaic panel is mounted in the first mount slot, and the sheet member is mounted in the second mount slot.

16. The photovoltaic device according to claim 15, wherein the heat sink module further comprises:
two leaning parts respectively disposed at two opposite sides of the sheet member, and disposed on a different plane from the sheet member,
wherein the leaning parts push against the fastening frame in the second mount slot towards the direction opposite to the photovoltaic panel, so that the sheet member leans against the rear surface of the photovoltaic panel.

17. The photovoltaic device according to claim 16, wherein the heat sink module further comprises:
a plurality of the at least one sheet member arranged at intervals on the rear surface of the photovoltaic panel.

18. The photovoltaic device according to claim 2, wherein the wind-facing surface of each of the fins faces a short side or a long side of the sheet member.

19. The photovoltaic device according to claim 1 further comprising:
a heat shrinkable unit covering the photovoltaic panel after being heated and shrunk, such that only the front surface of the photovoltaic panel is exposed.

20. The photovoltaic device according to claim 19, wherein the heat shrinkable unit comprises:
a main body;
a recessed slot formed on one surface of the main body for accommodating the fins and the photovoltaic panel;
a slot opening communicating with the recessed slot, and for exposing the front surface of the photovoltaic panel; and
a plurality of elongated holes arranged at a bottom of the recessed slot, the fins protruding into the elongated holes, respectively.

21. The photovoltaic device according to claim 20, wherein each of the fins is an individual member, and a cross section thereof is T-shaped, each of the fins comprising:
a transversal piece disposed between the heat shrinkable unit and the rear surface of the photovoltaic panel, one surface of the transversal piece being directly provided on the rear surface of the photovoltaic panel; and
a longitudinal piece perpendicular to the transversal piece, one side thereof being connected with the transversal piece, and the other side thereof protruding from one of the elongated holes.
